(19) United States
(12) Patent Application Publication
(10) Pub. No.: US 2025/0046609 A1
(43) Pub. Date: Feb. 6, 2025

(54) EUV DOSE REDUCING LAYERS, RELATED STRUCTURES, AND METHODS AND SYSTEMS FOR THEIR MANUFACTURE

(71) Applicant: ASM IP Holding B.V., Almere (NL)

(72) Inventors: Fatemeh Davodi, Helsinki (FI); Paul Chatelain, Tokyo (JP); Charles Dezelah, Helsinki (FI)

(21) Appl. No.: 18/792,784

(22) Filed: Aug. 2, 2024

Related U.S. Application Data
(60) Provisional application No. 63/517,739, filed on Aug. 4, 2023.

(51) Int. Cl. H01L 21/02; C23C 16/40; C23C 16/455; C23C 16/503; G03F 7/20; H01L 21/033

(52) U.S. Cl. CPC H01L 21/0257; C23C 16/40; C23C 16/45538; C23C 16/45553; C23C 16/503; G03F 7/2004; H01L 21/02565; H01L 21/033

(57) ABSTRACT

Methods and related systems and structures for reducing EUV dose requirements during lithography steps. Presently disclosed methods can comprise forming a dose reducing layer that comprises a doped semiconductor. The doped semiconductor can comprise at least one of an elemental semiconductor and a compound semiconductor.

### CROSS-REFERENCE TO RELATED APPLICATION(S)

This application claims the benefit of U.S. Provisional Application 63/517,739 filed on Aug. 4, 2023, the entire contents of which are incorporated herein by reference.

### FIELD OF INVENTION

The present disclosure generally relates to structures, methods, and systems used in the formation of semiconductor devices. More particularly, the disclosure relates to the field of extreme ultraviolet lithography.

### BACKGROUND OF THE DISCLOSURE

Semiconductor device patterning is often designed around the properties of expensive lithography equipment. Reducing the time needed per wafer during lithography steps can greatly improve throughput and costs of device fabrication, and this time can be expressed in terms of lithography dose.

Dose is equated to energy over a unit space, or in other terms, to the photon flux (number of photons per unit time per unit space) multiplied by the photon energy and exposure time. In the emerging field of EUV lithography, which improves resolution through decreased wavelength, the energy per photon is greatly increased. To reduce the dose, either the photon flux or the exposure time needs to be decreased, both of which reduces the total number of photons hitting the lithography resists to very low amounts. Moreover, high energy EUV photons are more difficult to absorb by most materials, exaggerating the issue of the low photon count. With such a low amount of photons absorbed by the resist, it is difficult to obtain a good quality lithography structure due to the photon shot noise effect, especially at the small structure sizes being pursued. Therefore, the key to practically decreasing dose is to increase the useful effect of each photon.

The usefulness of each photon may be improved through two ways: by increasing the absorption of each photon, and by increasing the number of electrons produced per photon. Absorption is often improved by simply inserting EUV absorbing materials into the lithography structure. This absorption produces photoelectrons which can cause reactions in the resist, but one electron per photon conversion still produces high shot noise. This problem is solved if the high energy photoelectrons are converted into multiple secondary electrons (SEs) through multiple possible pathways.

There are two main known solutions to incorporating EUV absorbing and SE producing materials into the lithography stack.

One solution is to directly add the materials to the resist such as by adding sensitizers to chemically amplified resists (CARs) or by using highly absorbing metal oxide resists (MORs). However, there are drawbacks to these new resists. Resists have become complicated structures that are difficult to control SE generation, and too high absorption in the resist can block further photons from traveling to the bottom of the resist where needed. Too long of electron path in the resist is also not desired as this will hurt resolution and cause roughness. If absorption is balanced so photons absorb at the resist bottom, SEs are still often lost to the substrate.

The second solution to compliment the above solution is to deposit the EUV absorbing and SE producing materials into the underlayers. These layers can be directly designed to produce many electrons and help to supply SEs to the resist bottom. However, many of the materials are heavy metals with self-limiting effects because electrons from deeper levels cannot easily move to the resist. Moreover, many of the randomly moving electrons are still lost to the substrate. Even if materials with longer electron paths are placed under these materials, electrons will still be blocked by the upper layers and lost to the substrate. Although many high absorption materials are known and can be deposited, a more precisely designed architecture is needed to control how the electrons are produced and whether they end up where needed, all while being incorporated into a low cost and very thin sacrificial patterning stack.

### SUMMARY OF THE DISCLOSURE

Disclosed are structures that can be used as, or employed in, lithographical patterning stacks during processing of semiconductor wafers. Also disclosed are methods and systems for producing such structures.

Advantageously, embodiments according to the present disclosure can allow to produce as much secondary electrons as possible.

Thus described herein is a structure comprising a substrate, a dose reducing layer overlying the substrate, and an extreme ultraviolet (EUV) resist overlying the dose reducing layer; wherein the dose reducing layer comprises a doped semiconductor, the doped semiconductor comprising a main component and a dopant.

In some embodiments, the doped semiconductor has a band gap of at least 2.0 eV.

In some embodiments, the EUV resist is selected from a metalorganic framework resist, a metal oxide resist, and a chemically amplified resist.

Further described herein is a method comprising: providing a substrate to a reaction chamber; forming dose reducing layer on the substrate; optionally forming a glue layer on the substrate; and, forming an EUV resist on the substrate; wherein: the EUV resist is arranged for absorbing EUV radiation and generating secondary electrons; and, the dose reducing layer comprises a main component and a dopant.

In some embodiments, the method further comprises a step of exposing the EUV resist to EUV radiation through a mask.

In some embodiments, the main component comprises an elementary semiconductor.

In some embodiments, the elementary semiconductor comprises tellurium.

In some embodiments, the main component comprises a compound semiconductor.

In some embodiments, the compound semiconductor comprises indium (III) oxide.

In some embodiments, the dopant comprises vacancies.

In some embodiments, the vacancies comprise oxygen vacancies.

In some embodiments, the dopant comprises iodine.

Further described herein is a method of forming a layer, the method comprising providing a substrate to a reaction chamber by means of a substrate handler; executing a cyclical deposition process, the cyclical deposition process comprising a plurality of cycles, ones from the plurality of cycles comprising a main component precursor pulse and a dopant reactant pulse, the main component precursor pulse comprising contacting the substrate with a main component precursor; the reactant pulse comprising contacting the substrate with a dopant reactant; wherein the main component precursor comprises tellurium; and wherein the dopant reactant comprises iodine.

In some embodiments, the main component precursor comprises diisopropyl telluride.

In some embodiments, the dopant reactant comprises an iodoalkane.

In some embodiments, the iodoalkane comprises 1,2-diiodoethane.

In some embodiments, the cyclical deposition process is a thermal cyclical deposition process.

In some embodiments, at least one of the precursor and the reactant comprise an active species, the active species being generated in a plasma.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a structure 100 as described herein.

FIG. 2 shows an embodiment of a system 200 as described herein.

FIG. 3 illustrates an embodiment of a method as described herein.

FIGS. 4-7 illustrate embodiments of systems as described herein.

FIG. 8 shows an embodiment of a method as described herein.

FIG. 9 shows an embodiment of a system as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, may include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

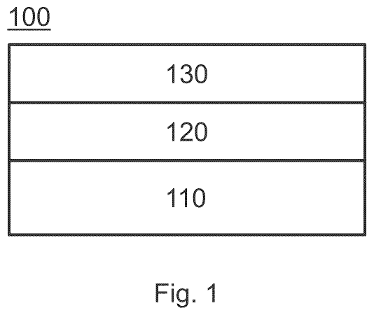

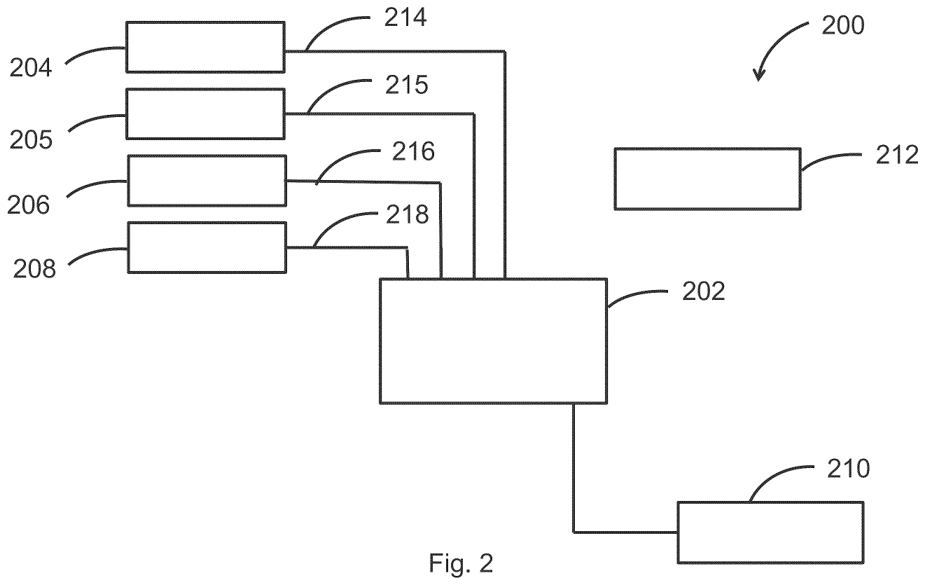

In some aspects, and referring to FIG. 1, described herein is a structure 100. The structure 100 can comprises a substrate 110, a dose reducing layer overlying the substrate 120, and an extreme ultraviolet (EUV) resist 130 overlying the dose reducing layer 120. The dose reducing layer 120 can comprise a doped semiconductor. The doped semiconductor can comprise a main component and a dopant.

The EUV resist can be constructed and arranged for absorbing EUV radiation and generating secondary electrons. An EUV resist layer may include any suitable resist, such as molecular, metal oxide, or chemically amplified resist. It shall be understood that the resists can be formed using any suitable deposition technique, including chemical vapor deposition (CVD), plasma-enhanced chemical vapor deposition (PECVD), atomic layer deposition (ALD), and plasma-enhanced atomic layer deposition (PEALD).

The dopant in the doped semiconductor can increase the conductivity of the doped semiconductor vis-à-vis an undoped variant. Some level of electrical conductivity can advantageously allow replenishing electrons lost secondary electron emission processes which can improve secondary electron generation in the dose reducing layer, which can in turn assist with lowering the required EUV dose for full resist exposure.

In some embodiments, incorporating the dopant in the dose reducing layer can reduce the electron affinity of the dose reducing layer, vis-à-vis the undoped version. This can increase the electron escape probability, which can in turn result in production of more secondary electrons.

In some embodiments, the dopant can have a relatively high capture cross section for EUV radiation, which can reduce the dose requirements of lithographical stacks.

In some embodiments, the doped semiconductor has a band gap of at least 2.0 eV. In some embodiments, the doped semiconductor has a band gap of at least 2.5 eV, of at least 3.0 eV, of at least 4.0 eV, with eV standing for “electron volts”.

In some embodiments, the doped semiconductor has a band gap of at most 6.0 eV, of at most 5.0 eV, or of at most 4.0 eV.

In some embodiments, the doped semiconductor has a band gap of at least 2.0 eV to at most 4.0 eV.

Materials with relatively wide band gaps, e.g. semiconductors with a relatively wide band gap, can inhibit, prevent, or limit energy loss of low-energy secondary electrons through electron-electron collisions, thereby resulting in a large escape depth for the secondary electrons and a large secondary-electron yield. Nevertheless, a band gap that is too high can make it difficult to make the doped material conductive by adding dopant elements, such that there can be a practical limit on the maximum band gap that is practical.

In some embodiments, the doped semiconductor comprises a compound semiconductor. In other words, the main component of the doped semiconductor can comprise a compound semiconductor.

Suitable compound semiconductors include semiconducting oxides.

In some embodiments, the doped semiconductor comprises indium oxide, e.g. indium (III) oxide, i.e. In₂O₃. In other words, the main component of the doped semiconductor can comprise In₂O₃. In some embodiments, when the main component of the doped semiconductor comprises In₂O₃, the dopant can comprise iodine.

In some embodiments, the doped semiconductor comprises tin oxide, e.g. tin (IV) oxide, i.e. SnO₂. In other words, the main component of the doped semiconductor can comprise SnO₂. In some embodiments, when the main component of the doped semiconductor comprises tin oxide, the dopant can comprise iodine.

In some embodiments, the doped semiconductor comprises antimony oxide. In other words, the main component of the doped semiconductor can comprise antimony oxide. In some embodiments, when the main component of the doped semiconductor comprises antimony, the dopant can comprise iodine. In some embodiments, the doped semiconductor can comprise antimony oxide, such as iodine-doped antimony oxide. Antimony can be in a +III or a +V oxidation state. In some embodiments, antimony oxide can comprise an oxide, e.g. a non-stoichiometric oxide, e.g. of the form Sb₂Oₓ with x being a real number from at least 3 to at most 5. In some embodiments, x is 3. In some embodiments, x is 4. In some embodiments, x is 5.

In some embodiments, the doped semiconductor comprises tellurium oxide. In other words, the main component of the doped semiconductor can comprise tellurium oxide. In some embodiments, when the main component of the doped semiconductor comprises tellurium oxide, the dopant can comprise iodine.

In some embodiments, for example when the doped semiconductor comprises a semiconducting oxide such as indium oxide, tin oxide, antimony oxide, or tellurium oxide, the dopant can comprise oxygen vacancies.

Suitable compound semiconductors include semiconducting halides, such as semiconducting iodides or bromides. In some embodiments, the main component of the doped semiconductor comprises tin iodide. In such embodiments, the dopant can comprise a chalcogenide such as tellurium.

In some embodiments, the doped semiconductor comprises an elementary semiconductor. Suitable elementary semiconductors include tellurium, i.e. Te. In other words, the main component of the doped semiconductor can comprise tellurium.

In some embodiments, for example when the main component of the doped semiconductor comprises tellurium, the dopant can comprise a halogen such as iodine.

Advantageously, the dopant can have a relatively high capture cross section for EUV radiation. For example, the dopant can have a an EUV cross section (σα) of greater than 2×10⁶ cm²/mol. For example, the dopant can include one or more of lead (Pb), cesium (Cs), bismuth (Bi), indium (In), aluminum (Al), magnesium (Mg), titanium (Ti), yttrium (Y), lanthanum (La), strontium (Sr), terbium (Tb), antimony (Sb), tellurium (Te), germanium (Ge), hafnium (Hf), and ytterbium (Yb).

In some embodiments, the dopant comprises a halogen. Suitable halogens include bromine and iodine. For example, halogens such as iodine and bromine can be employed for doping a stoichiometric or non-stoichiometric semiconductor, such as a semiconducting oxide. For example, the bromine- or iodine-doped semiconductor can be selected from the list consisting of silicon oxycarbide, silicon oxide, tellurium oxide, tin oxide, indium oxide, and germanium oxide.

In some embodiments, the dopant comprises an alkaline metal. Suitable alkaline metals include cesium.

In some embodiments, the dopant comprises a chalcogenide. Suitable chalcogenides include selenium.

A dose reducing layer according to the present disclosure can be formed by means of any suitable method, for example by means of atomic layer deposition (ALD) or chemical vapor deposition (CVD).

Further described herein are methods of forming a layer. Suitably, the layer can be employed as a dose reducing layer as described herein. In some embodiments, a method as described herein can comprise providing a substrate to a reaction chamber. This can be done, for example, by means of a substrate handler such as a segmented robot arm, a linear actuator, a rotary actuator, a conveyor belt, an air cushion, or the like.

A method according to an embodiment of the present disclosure can further comprise executing a cyclical deposition process. The cyclical deposition process can comprise a plurality of cycles. Ones from the plurality of cycles can comprise a main component precursor pulse and a dopant reactant pulse. The main component precursor pulse can comprise contacting the substrate with a main component precursor. The dopant reactant pulse can comprise contacting the substrate with a dopant reactant.

In some embodiments, the layer, e.g. dose reducing layer, can comprise a doped elemental semiconductor. Suitable elemental semiconductors include diamond, diamond-like carbon, tin, indium, selenium, germanium, antimony, and tellurium.

In some embodiments, the main component precursor comprises a carbon precursor and the dopant reactant comprises a boron reactant. Thus, a layer, e.g. dose reducing layer comprising boron-doped diamond, or boron-doped diamond-like carbon, can be made, which can have excellent secondary electron yield. Nitrogen is a deep donor in diamond, and at room temperature N-doped diamond samples are insulators. It has been shown that the secondary electron yield (SEY) from the N-doped diamond are very low. In contrast, boron is a shallow acceptor in diamond, and therefore boron-doped diamond samples are advantageously conductive and have higher SEY.

In some embodiments, the cyclical deposition process comprises a main component precursor pulse, a main component reactant pulse employing an oxygen reactant, and a dopant reactant pulse. A main component reactant pulse employing an oxygen reactant can be referred to as an oxygen reactant pulse. The main component precursor pulse can comprise contacting the substrate with a precursor. The reactant pulse can comprise contacting the substrate with a dopant reactant. The oxygen reactant pulse comprises contacting the substrate with an oxygen reactant.

In some embodiments, the oxygen reactant comprises an oxygen-containing gas such as N₂O, NO, NO₂, NO₃, N₂O₄, N₂O₅, H₂O, H₂O₂, O₂, or O₃.

In some embodiments, the oxygen reactant comprises an active species. Suitable active species include ions and radicals. Active species can be generated using a plasma. In some embodiments, the plasma contacts the substrate. Suitable plasmas can be generated using a plasma gas that comprises O₂, a so-called O₂ plasma, which can suitably generate oxygen atoms and oxygen radicals which may be used individually or in combination as an oxygen reactant.

When a relatively strong oxygen reactant such as O₃ or an O₂ plasma is used, an oxide semiconductor with a low or negligible amount of oxygen vacancies can ensue, with a resistive film as a result. For instance, doped In₂O₃ can be made using a main component precursor that comprises indium, i.e. an indium precursor, a dopant reactant, and a main component reactant that comprises oxygen, i.e. an oxygen reactant. When O₃ used as an oxygen reactant, the process produces a more perfect In₂O₃ stoichiometry with fewer oxygen vacancies compared to the one produced with water as the oxygen reactant, resulting in increased resistivity and less secondary electron emission consequently. Incorporating dopants in such high resistivity films can advantageously increase conductivity and therefore electron emission. In some embodiments, indium oxide can be doped with one or more dopants selected from cesium, iodine, and tellurium.

In some embodiments, the main component precursor comprises a tellurium precursor comprising tellurium. In some embodiments, the tellurium precursor is selected from Te(OEt)₄, Te(SiMe₃)₂, Te(SiEt₃)₂, TeCl₄, and TeRR′ where R and R′ are independently any C1-C6 alkyl or alkenyl. It shall be understood that Et stands or ethyl and Me for methyl. In some embodiments, the tellurium precursor is selected from Te(vinyl)₄, Te(allyl)₄, Te(iPr)₂, Te chloride, Te ethoxide, Te[NH(Si(CH₃)₃)]₂.

In some embodiments, the main component precursor comprises a tin precursor comprising tin. In some embodiments, the tin precursor is selected from a tin alkenyl such as Sn(vinyl)₄ and Sn(allyl)₄, a tin alkyl such as SnMe₄, and a tin alkylamine such as tetrakis(dimethylamido)tin(IV). In some embodiments, the tin precursor is selected from a tin halide such as SnCl₄, a tin alkyl such as SnHBu₃, dimethylamino-2-methyl-2-propoxy-tin(II) (Sn(dmamp)₂), bis(diisopropylacetamidinato) tin(II) (Sn(iPr₂AMD)₂), bis(N,N′-diisopropylformamidinato) tin(II) (Sn(iPr₂FMD)₂), tin alkylamines such as Sn(NEtMe)₄, tin alkoxides such as Sn(OtBu)₄, tin halides such as SnI₄, tin alkyls such as SnEt₄, and tin β-diketonates such as tin(II) acetylacetonate (Sn(acac)₂). It shall be understood that Me stands for methyl, Bu for butyl, and tBu for tert-butyl.

In some embodiments, the main component precursor comprises an antimony precursor comprising antimony. In some embodiments, the antimony precursor can comprise one or more of antimony halides such as SbCl₃ and SbCl₅, antimony alkylsilyl such as Sb(SiMe₃)₃ and Sb(SiEt₃)₃, antimony alkylamines such as Sb(NMe₂)₃, antimony alkyls such as SbEt₃ and SbR₃ where R is C1-C6 alkyl, antimony alkoxides such as SbOEt₃. It shall be understood that Me stands for methyl, that Et stands for ethyl, and that OEt stands for ethoxide.

In some embodiments, the dopant reactant comprises a halogen. Exemplary halogens include fluorine, chlorine, bromine, and iodine.

In some embodiments, the dopant reactant comprises iodine. Suitable iodine-containing reactants include iodoalkanes such as 1,2-diiodoethane, CH₃I, and CH₂I₂. In some embodiments, the dopant reactant can comprise a metal iodide such as a post transition metal iodide such as SnI₄. In some embodiments, the dopant reactant comprises elemental iodine, I₂. In some embodiments, the dopant reactant comprises an iodine-substituted saturated or unsaturated cyclic hydrocarbon, such as an iodine-substituted saturated cyclic hydrocarbon, such as cyclopentyl iodide or cyclohexyl iodide. In some embodiments, the dopant reactant is selected from the list of C1-C10 iodoalkyls, C2-C10 iodoalkenyls, and C6-C10 iodoaryl, which can comprise from at least 1 to 4 iodine atoms. In some embodiments, the dopant reactant is selected from the list consisting of diiodomethane, 1,2-diiodoethane, 1-iodobutane, 1-iodohexane, iodobenzene, iodotoluene, allyl iodide, and vinyl iodide.

In some embodiments the dopant reactant comprises bromine. Suitable bromine-containing reactants include bromoalkanes such as 1,2-dibromoethane, CH₃Br, and CH₂Br₂. In some embodiments, the dopant reactant can comprise a metal bromide such as a post transition metal bromide such as SnBr₄. In some embodiments, the dopant reactant comprises elemental bromine, Br₂.

In some embodiments, the dopant reactant comprises a hydrocarbyl iodide, for example an iodinated C1-C10 straight chain or branched alkyl, or an iodinated C6-C10 substituted aryl, where the alkyl or aryl can comprise one to four iodine atoms that can be on the same, adjacent, or non-adjacent atoms. In some embodiments, the dopant reactant comprises a compound selected from the list consisting of phenyl iodide, 1-iodohexane, and 1-iodo-butane.

In some embodiments, the dopant reactant comprises a hydrocarbyl bromide, for example a brominated C1-C10 straight chain or branched alkyl, or a brominated C6-C10 substituted aryl, where the alkyl or aryl can comprise one to four bromine atoms that can be on the same, adjacent, or non-adjacent atoms. In some embodiments, the dopant reactant comprises a compound selected from the list consisting of phenyl bromide, 1-bromohexane, and 1-bromo-butane.

In some embodiments, the dopant reactant is selected from the list consisting of HBr, HI, N-bromosuccinimide, N-iodosuccinimide, TiBr₄, and TiI₄.

In some embodiments, the dopant reactant comprises cesium, i.e. comprises a cesium reactant. Suitable cesium reactants comprise alkylsilyl amides such as cesium bis(trimethylsilyl) amide, Cs[Y(β-diketonato)₄] type precursors such as Cs[Y(ptac)₄], and cesium halides such as CsI. It shall be understood that-diketonato ligands can be of the general formula CF₃COCHCOR, with R being tert-butyl in the case of ptac, R being CF₃ in the case of hfac, R being methyl in the case of tfac, and R being phenyl in the case of btfac. Suitable cesium alkoxides included branched or linear alkoxides, such as C3 to C7 alkoxides, such as Cs(OtBu) in which OtBu stands for tert-butoxide.

In some embodiments, the dopant reactant comprises a selenium reactant that comprises selenium. Suitable selenium reactants include SeO₂, selenium halides such as SeCl₄, H₂Se, selenium alkylsilyls such as Se (SiMe₃)₂ and Se (SiEt₃)₂, and selenium alkyls such as Se₂Et₂ and SeEt₂, with Me being methyl and Et being ethyl.

In some embodiments, the main component reactant comprises oxygen. In other words, the main component reactant can comprise an oxygen reactant. Suitable oxygen reactants can be selected from the list comprising O₃, O₂, H₂O, H₂O₂, N₂O, NO, NO₂, and NO₃.

In some embodiments, the cyclical deposition process is a thermal cyclical deposition process. A thermal process can comprise activating a chemical reaction by means of thermal energy. Thermal processes can be contrasted with plasma processes in which a plasma can be employed for generating active species such as ions or radicals which can activate chemical reactions at comparatively lower temperatures.

A thermal cyclical deposition process may be carried out in an embodiment of a system 200 in accordance with exemplary embodiments of the disclosure. The system 200 can be used to perform a method as described herein and/or form a structure or device portion as described herein.

In the illustrated example, the system 200 includes one or more reaction chambers 202, a first precursor gas source 204, a reactant gas source 206, a purge gas source 208, an exhaust 210, and a controller 212.

The reaction chamber 202 can include any suitable reaction chamber, such as an ALD or CVD reaction chamber.

The first precursor gas source 204 can include a vessel and one or more precursors as described herein-alone or mixed with one or more carrier (e.g., noble) gases. The second precursor gas source 206 can include a vessel and one or more reactants as described herein-alone or mixed with one or more carrier gases.

The purge gas source 208 can include one or more noble gases as described herein. Although illustrated with four gas sources 204-208, the system 200 can include any suitable number of gas sources. The gas sources 204-208 can be coupled to reaction chamber 202 via lines 214-218, which can each include flow controllers, valves, heaters, and the like.

The exhaust 210 can include one or more vacuum pumps.

The controller 212 includes electronic circuitry and software to selectively operate valves, manifolds, heaters, pumps and other components included in the system 200. Such circuitry and components operate to introduce precursors and purge gases from the respective sources 204-208. The controller 212 can control timing of gas pulse sequences, temperature of the substrate and/or reaction chamber, pressure within the reaction chamber, and various other operations to provide proper operation of the system 200. The controller 212 can include control software to electrically or pneumatically control valves to control flow of precursors, reactants and purge gases into and out of the reaction chamber 202. The controller 212 can include modules such as a software or hardware component, e.g., a FPGA or ASIC, which performs certain tasks. A module can advantageously be configured to reside on the addressable storage medium of the control system and be configured to execute one or more processes.

Other configurations of the system 200 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 202. Further, as a schematic representation of a system, many components have been omitted for simplicity of illustration, and such components may include, for example, various valves, manifolds, purifiers, heaters, containers, vents, and/or bypasses.

During operation of the reactor system 200, substrates, such as semiconductor wafers (not illustrated), are transferred from, e.g., a substrate handling system to the reaction chamber 202. Once substrate(s) are transferred to the reaction chamber 202, one or more gases from the gas sources 204-208, such as precursors, reactants, carrier gases, and/or purge gases, are introduced into the reaction chamber 202.

An embodiment of a reactor system 200 can be employed for executing a cyclical deposition process, such as an atomic layer deposition process, as described herein.

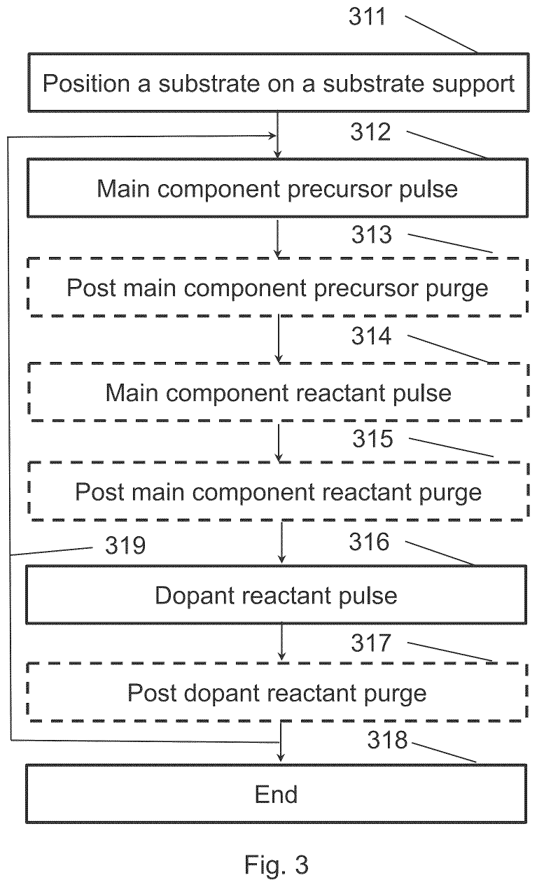

A schematic representation of an embodiment of a cyclical deposition process such as an atomic layer deposition process is shown in FIG. 3. The process comprises a step 311 of positioning a substrate on a substrate support. The process comprises a plurality of deposition cycles 319. Ones from the plurality of deposition cycles can comprise a main component precursor pulse 312, an optional post main component precursor purge 313, an optional main component reactant pulse 314, an optional post main component reactant purge 315, a dopant reactant pulse 316, and a post dopant reactant purge 317. After a pre-determined number of deposition cycles 319 have been executed, the process can end 318.

The main component precursor pulse 312 can comprise exposing the substrate to a main component precursor as described herein. The post main component precursor purge 313 can comprise exposing the substrate to a purge gas as described herein. The main component reactant pulse 314 can comprise exposing the substrate to a main component reactant as described herein. The post main component reactant purge 315 can comprise exposing the substrate to a purge gas as described herein. The dopant reactant pulse 316 can comprise exposing the substrate to a dopant reactant as described herein. The post dopant reactant purge 317 can comprise exposing the substrate to a purge gas as described herein.

In some embodiments, at least one of the precursor and the reactant comprise an active species. In some embodiments, the active species is generated in a plasma.

In some embodiments, the dose reducing layer comprises iodine-doped tin oxide. Such a dose reducing layer can be advantageously made using a plasma-enhanced cyclical deposition process, for example by means of plasma-enhanced atomic layer deposition. An exemplary embodiment of a plasma-enhanced cyclical deposition process can comprise a plurality of deposition cycles. A deposition cycle can comprise, in the given order, a precursor pulse, a first plasma pulse, reactant pulse, and a second plasma pulse. The precursor pulse can comprise exposing the substrate to a tin precursor. The first plasma pulse can comprise exposing the substrate to an oxygen plasma, i.e. to a plasma generated using a plasma gas that comprises oxygen and optionally a noble gas such as He or Ar. The reactant pulse can comprise exposing the substrate to a halogen-containing reactant, e.g. an iodine-containing reactant. The second plasma pulse can comprise exposing the substrate to a noble gas plasma, such as to an argon plasma.

In some embodiments, a dose reducing layer comprising a halogen-doped tin oxide, e.g. an iodine-doped tin oxide, can be manufactured by first forming a tin oxide layer, and subsequently exposing the tin oxide layer to a halogen-containing reactant, e.g. an iodine-containing reactant. For example, the tin oxide layer can be formed using thermal or plasma-enhanced atomic layer deposition.

For example, a dose reducing layer can be manufactured using an embodiment of the process described in FIG. 3. In some embodiments, manufacturing such a dose reducing layer can comprise generating a plasma during one or more steps of the embodiment of FIG. 3. For example, the main component precursor pulse 312 can comprise generating active species using a plasma. For example, the post main component precursor purge 313 can comprise generating active species using a plasma. For example, the main component reactant pulse 314 can comprise generating active species using a plasma and exposing the substrate to these active species. For example, the post main component reactant purge 315 can comprise generating active species using a plasma and exposing the substrate to these active species. For example, the dopant reactant pulse 316 can comprise generating active species using a plasma and exposing the substrate to these active species. For example, the post dopant reactant purge 317 can comprise generating active species using a plasma and exposing the substrate to these active species. Active species can include at least one of ions and radicals.

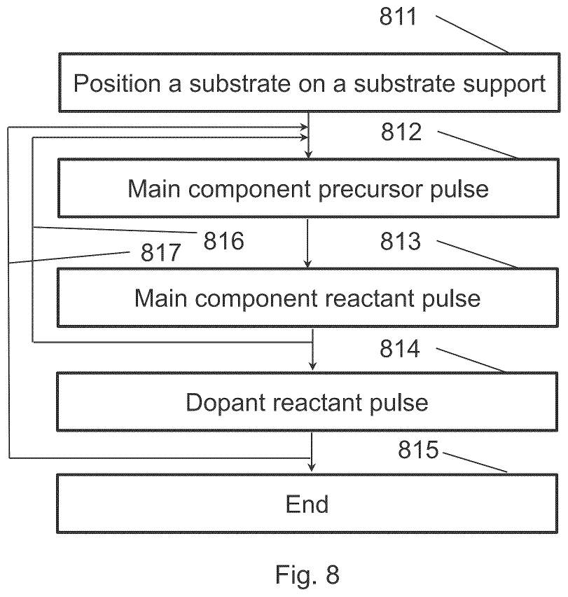

In some embodiments, a dose reducing layer can be manufactured using an embodiment of the process described in FIG. 8. The process of FIG. 8 comprises a step 811 of positioning a substrate on a substrate support. Then the process comprises executing a plurality of super cycles 817. Ones from the plurality of super cycles 817 comprise a dopant reactant pulse 814 and one or more, e.g. a plurality of, sub cycles 816. Individual sub cycles comprise a main component precursor pulse 812 and a main component reactant pulse 813. After a pre-determined amount of super cycles has been executed, a layer having a suitable thickness has been deposited, and the process ends 815. Optionally, one or more of the aforementioned pulses can be separated by means of a purge step.

The main component precursor pulse 812 can comprise exposing the substrate to a main component precursor as described herein. The main component reactant pulse 813 can comprise exposing the substrate to a main component reactant as described herein. The dopant reactant pulse 814 can comprise exposing the substrate to a dopant reactant as described herein. In some embodiments, the dopant reactant comprises a dopant precursor and the dopant reactant pulse can occur thermally, i.e. without exposing the substrate to active species that are generated in plasma. In some embodiments, the dopant reactant pulse can comprise exposing the substrate to one or more active species such as ions and radicals that were generated in a plasma.

In an exemplary embodiment, and in a process according to an embodiment of the process of FIG. 8, the main component precursor can comprise indium, the main component reactant can comprise oxygen, and the dopant reactant can comprise an active species such as at least one of radicals or ions. Suitable radicals include hydrogen radicals. Suitable ions include oxygen ions. Suitably at least one of the hydrogen radicals and the oxygen radicals can be generated in a hydrogen plasma. Suitable hydrogen plasmas can comprise a hydrogen source such as H₂ and a noble gas such as He, Ne, Ar, Xe, or Kr. Advantageously, an indium oxide layer can thus be obtained that contains oxygen vacancies. The oxygen vacancies can act as dopants.

In some embodiments, a method as described herein can comprise exposing the substrate to a plasma, such as a hydrogen plasma. “Hydrogen plasma” can refer to a plasma in which the plasma gas comprises hydrogen, for example together with one or more noble gasses such as He, Ne, Ar, Kr, or Xe.

In some embodiments, a hydrogen plasma post deposition treatment can be applied when the main component of the doped semiconductor comprises a compound semiconductor such as a semiconducting oxide, such as In₂O₃.

Advantageously, a hydrogen plasma post treatment can withdraw one or more constituent elements from the doped semiconductor, e.g. oxygen from a semiconducting oxide, which can result in creation of oxygen vacancies. Oxygen vacancies can act as electron donor sites, i.e. n-type dopants, thereby enhancing conductivity in the semiconducting oxide, which can in turn enhance secondary electron yield from the dose reducing layer.

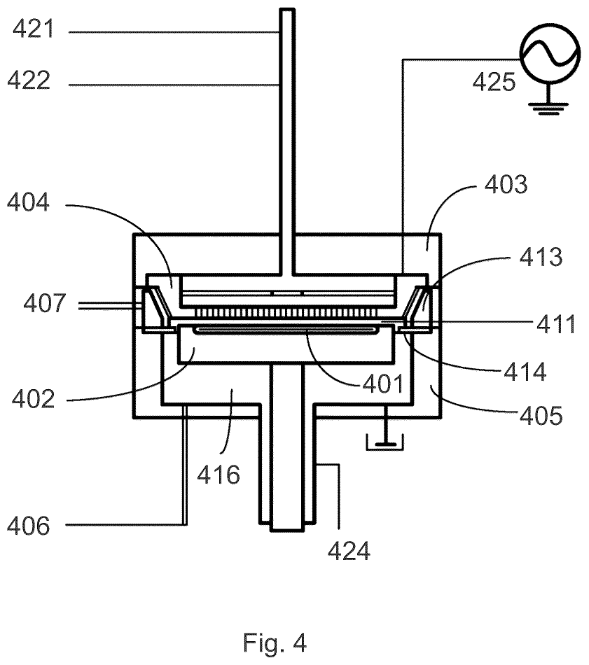

Layers formed in methods according to the present disclosure may be formed in any suitable apparatus, including in a reactor as shown in FIG. 4. Similarly, the presently provided structures or parts thereof may be manufactured in any suitable apparatus, including a reactor as shown in FIG. 4. FIG. 4 is a schematic view of a plasma-enhanced atomic layer deposition (PEALD) apparatus, desirably in conjunction with controls programmed to conduct the sequences described below, usable in some embodiments of the present disclosure. In this figure, by providing a pair of electrically conductive flat-plate electrodes 402,404 in parallel and facing each other in the interior 411 (reaction zone) of a reaction chamber 403, applying RF power (e.g. at 13.56 MHz and/or 27 MHz) from a power source 425 to one side, and electrically grounding the other side 412, a plasma is excited between the electrodes.

A temperature regulator may be provided in a lower stage 402, i.e. the lower electrode. A substrate 401 is placed thereon and its temperature is kept constant at a given temperature. The upper electrode 404 can serve as a shower plate as well, and a reactant gas and/or a dilution gas, if any, as well as a precursor gas can be introduced into the reaction chamber 403 through a gas line 421 and a gas line 422, respectively, and through the shower plate 404. Additionally, in the reaction chamber 403, a circular duct 413 with an exhaust line 417 is provided, through which the gas in the interior 411 of the reaction chamber 403 is exhausted. Additionally, a transfer chamber 405 is disposed below the reaction chamber 403 and is provided with a gas seal line 424 to introduce seal gas into the interior 411 of the reaction chamber 403 via the interior 416 of the transfer chamber 405 wherein a separation plate 414 for separating the reaction zone and the transfer zone is provided. Note that a gate valve through which a wafer may be transferred into or from the transfer chamber 405 is omitted from this figure. The transfer chamber is also provided with an exhaust line 406. In some embodiments, forming the dose reducing layer and forming the EUV resist are done in one and the same reaction chamber. In some embodiments, they can be formed in separate reaction chambers comprised in one cluster system in which substrates are transferable from one reaction chamber to another without breaking vacuum, or while maintaining said substrates in an inert gas environment, such as in a noble gas environment.

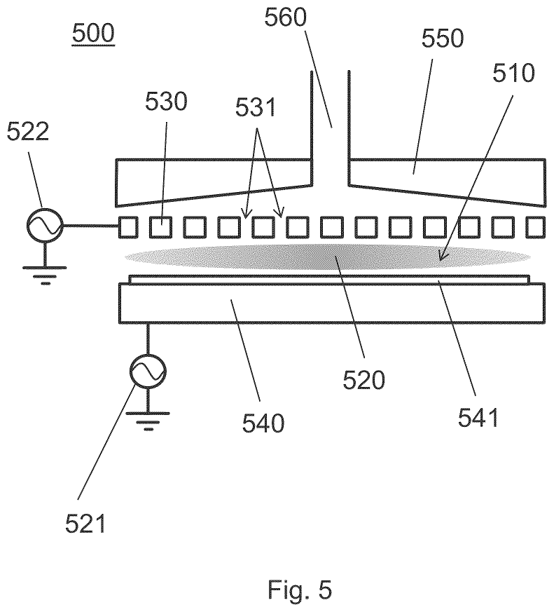

FIG. 5 shows a schematic representation of an embodiment of a sub-system 500 as described herein. It can be used, for example, for forming at least one of a dose reducing layer and an EUV resist. The sub-system 500 comprises a reaction chamber 510 in which a plasma 520 is generated. In particular, the plasma 520 is generated between a showerhead injector 530 and a substrate support 540. This is a direct plasma configuration employing a capacitively coupled plasma. In the configuration shown, the sub-system 500 comprises two alternating current (AC) power sources: a high frequency power source 521 and a low frequency power source 522. In the configuration shown, the high frequency power source 521 supplies radio frequency (RF) power to the showerhead injector, and the low frequency power source 522 supplies an alternating current signal to the substrate support 540. The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz. Process gas comprising precursor, reactant, or both, is provided through a gas line 560 to a conical gas distributor 550. The process gas then passes through holes 531 in the showerhead injector 530 to the reaction chamber 510.

Whereas the high frequency power source 521 is shown as being electrically connected to the showerhead injector, and the low frequency power source 522 is shown as being electrically connected to the substrate support 540, other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

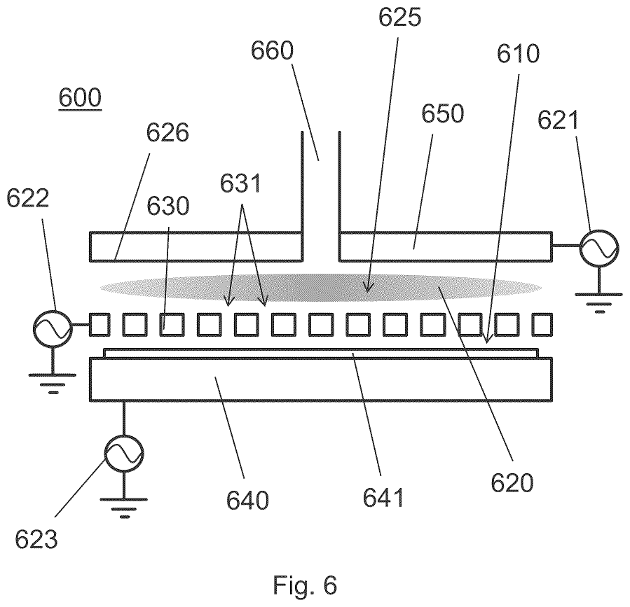

FIG. 6 shows a schematic representation of another embodiment of a sub-system 600 as described herein. It can be used, for example, for forming at least one of a dose reducing layer and an EUV resist. The configuration of FIG. 6 can be described as an indirect plasma system. The sub-system 600 comprises a reaction chamber 610 which is separated from a plasma generation space 625 in which a plasma 620 is generated. In particular, the reaction chamber 610 is separated from the plasma generation space 625 by a showerhead injector, and the plasma 620 is generated between the showerhead injector 630 and a plasma generation space ceiling 626.

In the configuration shown, the sub-system 600 comprises three alternating current (AC) power sources: a high frequency power source 621 and two low frequency power sources 622,623: a first low frequency power source 622 and a second low frequency power source 623. In the configuration shown, the high frequency power source 621 supplies radio frequency (RF) power to the plasma generation space ceiling, the first low frequency power source 622 supplies an alternating current signal to the showerhead injector 630, and the second low frequency power source 623 supplies an alternating current signal to the substrate support 640. A substrate 641 is provided on the substrate support 640. The radio frequency power can be provided, for example, at a frequency of 13.56 MHz or higher. The low frequency alternating current signal of the first and second low frequency power sources 622,623 can be provided, for example, at a frequency of 2 MHz or lower.

Process gas comprising precursor, reactant, or both, is provided through a gas line 660 that passes through the plasma generation space ceiling 626, to the plasma generation space 625. Active species such as ions and radicals generated by the plasma 625 from the process gas pass through holes 631 in the showerhead injector 630 to the reaction chamber 610.

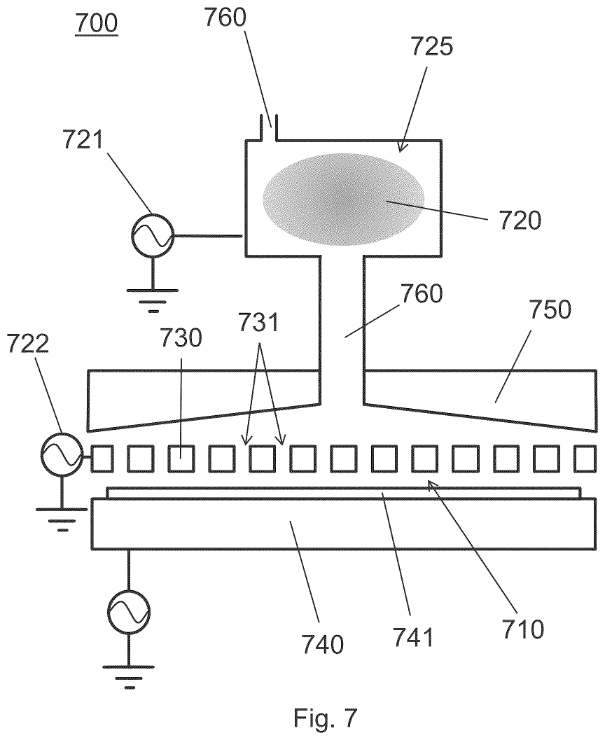

FIG. 7 shows a schematic representation of another embodiment of a sub-system 700 as described herein. It can be used, for example, for forming at least one of a secondary electron reflection layer, a secondary electron generation layer, a glue layer, and an EUV resist. The configuration of FIG. 7 can be described as a remote plasma system. The sub-system 700 comprises a reaction chamber 710 which is operationally connected to a remote plasma source 725 in which a plasma 720 is generated. Any sort of plasma source can be used as a remote plasma source 725, for example an inductively coupled plasma, a capacitively coupled plasma, or a microwave plasma.

In particular, active species are provided from the plasma source 725 to the reaction chamber 710 via an active species duct 760, to a conical distributor 750, through holes 731 in a shower plate injector 730, to the reaction chamber 710. Thus, active species can be provided to the reaction chamber in a uniform way.

In the configuration shown, the sub-system 700 comprises three alternating current (AC) power sources: a high frequency power source 721 and two low frequency power sources 722,723: a first low frequency power source 722 and a second low frequency power source 723. In the configuration shown, the high frequency power source 721 supplies radio frequency (RF) power to the plasma generation space ceiling, the first low frequency power source 722 supplies an alternating current signal to the showerhead injector 730, and the second low frequency power source 723 supplies an alternating current signal to the substrate support 740. A substrate 741 is provided on the substrate support 740. The radio frequency power can be provided, for example, at a frequency of 13.56 MHz or higher. The low frequency alternating current signal of the first and second low frequency power sources 722,723 can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source 725 by means of a gas line 760. Active species such as ions and radicals generated by the plasma 725 from the process gas are guided to the reaction chamber 710.

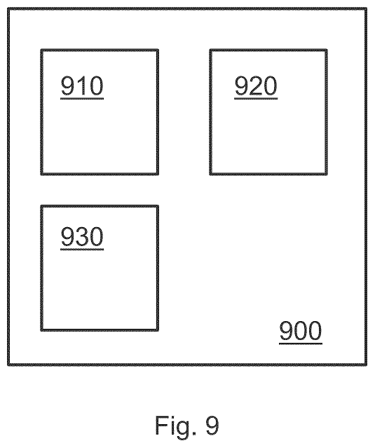

With reference to FIG. 9, further described herein is an embodiment of a system 900 that can be employed for forming a structure comprising a dose reducing layer and an EUV resist. The structure can be formed on a substrate that is kept in vacuum or an inert gas environment during and between formation of the dose reducing layer and the EUV resist. The system 900 comprises a dose reducing layer reaction chamber 910 that is constructed and arranged for forming a dose reducing layer on a substrate. The system 900 further comprises an EUV resist reaction chamber 920 that is constructed and arranged for forming an EUV resist on the dose reducing layer. The system further comprises a wafer handling robot 930 that is constructed and arranged for moving the substrate from the dose reducing layer reaction chamber 910 to the EUV resist reaction chamber 920. Advantageously, this can be done without breaking vacuum, or while keeping the substrate in an inert, i.e. unreactive, gas environment such as a noble gas environment.

In an exemplary embodiment, reference is made to FIG. 1 which shows an embodiment of a structure 100 in which the dose reducing layer 120 comprises iodine-doped tellurium. The dose reducing layer comprised carbon which can advantageously tune the surface free energy of the dose reducing layer to a desired value. The dose reducing layer was formed by means of a plasma-enhanced cyclical deposition process. The cyclical deposition process comprised a plurality of cycles. Ones from the plurality of cycles comprised, in the order given, a tellurium precursor pulse, an argon plasma step, an iodine reactant pulse, and a post iodine reactant purge. The tellurium precursor pulse comprises exposing the substrate to a tellurium precursor. The argon plasma step comprises exposing the substrate to an argon plasma. The iodine reactant pulse comprises exposing the substrate to an iodine reactant. The post iodine reactant purge comprises exposing the substrate to a purge gas such as a noble gas such as argon. Note that the substrate was not exposed to a plasma between subsequent iodine reactant pulses and tellurium precursor pulses. In other words, the post iodine reactant purge was executed thermally. Diisopropyltelluride was used as a tellurium precursor. 1,2-diiodoethane was used as a iodine precursor. Other iodoalkanes, e.g. diiodoalkanes, such as diiodomethane, may be alternatively used as an iodine precursor. The results featured an iodine-to-tellurium ratio of 17 to 39 atomic percent and advantageously had a low roughness. Advantageously, 13 percent dose reduction was obtained.

1. A structure comprising
a substrate;
a dose reducing layer overlying the substrate; and
an extreme ultraviolet (EUV) resist overlying the dose reducing layer,
wherein the dose reducing layer comprises a doped semiconductor, the doped semiconductor comprising a main component and a dopant.

2. The structure according to claim 1, wherein the doped semiconductor has a band gap of at least 2.0 eV.

3. The structure according to claim 1, wherein the EUV resist is selected from a metalorganic framework resist, a metal oxide resist, and a chemically amplified resist.

4. A method comprising:
providing a substrate to a reaction chamber;
forming dose reducing layer on the substrate;
optionally forming a glue layer on the substrate; and
forming an EUV resist on the substrate;
wherein:
the EUV resist is arranged for absorbing EUV radiation and generating secondary electrons; and
the dose reducing layer comprises a main component and a dopant.

5. The method according to claim 4 further comprising a step of exposing the EUV resist to EUV radiation through a mask.

6. The structure according to claim 1, wherein the main component comprises an elementary semiconductor.

7. The structure according to claim 6, wherein the elementary semiconductor comprises tellurium.

8. The structure according to claim 1, wherein the main component comprises a compound semiconductor.

9. The structure according to claim 8, wherein the compound semiconductor comprises indium (III) oxide.

10. The structure according to claim 8, wherein the dopant comprises vacancies.

11. The structure according to claim 10, wherein the vacancies comprise oxygen vacancies.

12. The structure according to claim 1, wherein the dopant comprises iodine.

13. A method of forming a layer, the method comprising
providing a substrate to a reaction chamber by a substrate handler; and
executing a cyclical deposition process, the cyclical deposition process comprising a plurality of cycles, ones from the plurality of cycles comprising a main component precursor pulse and a dopant reactant pulse,
the main component precursor pulse comprising contacting the substrate with a main component precursor;
the dopant reactant pulse comprising contacting the substrate with a dopant reactant;
wherein the main component precursor comprises tellurium; and wherein the dopant reactant comprises iodine.

14. The method according to claim 13, wherein the main component precursor comprises a tellurium alkyl.

15. The method according to claim 14 wherein the tellurium alkyl comprises diisopropyl telluride.

16. The method according to claim 14, wherein the dopant reactant comprises an iodoalkane.

17. The method according to claim 16, wherein the iodoalkane comprises 1,2-diiodoethane.

18. The method according to claim 13, wherein the cyclical deposition process is a thermal cyclical deposition process.

19. The method according to claim 13, wherein at least one of the main component precursor and the dopant reactant comprise an active species, the active species being generated in a plasma.
